(19) United States
(12) Patent Application Publication
(10) Pub. No.: US 2022/0002900 A1
(43) Pub. Date: Jan. 6, 2022

(54) THIN-FILM HEAT INSULATION SHEET FOR MONOCRYSTALLINE SILICON GROWTH FURNACE AND MONOCRYSTALLINE SILICON GROWTH FURNACE

(71) Applicants: Shanghai Institute of Microsystem and Information Technology, Chinese Academy of Sciences, Shanghai (CN); Zing Semiconductor Corporation, Shanghai (CN)

(72) Inventors: Xing Wei, Shanghai (CN); Tao Wei, Shanghai (CN); Minghao Li, Shanghai (CN); Zhan Li, Shanghai (CN); Yun Liu, Shanghai (CN); Zhongying Xue, Shanghai (CN)

(21) Appl. No.: 17/137,387

(22) Filed: Dec. 30, 2020

(30) Foreign Application Priority Data
Jul. 1, 2020 (CN) 202010625055.7

(51) Int. Cl. C30B 15/14; C30B 29/06

(52) U.S. Cl. CPC C30B 15/14; C30B 29/06

(57) ABSTRACT

Disclosed is a thin-film heat insulation sheet for a monocrystalline silicon growth furnace, which comprises one or more first refractive layers and one or more second refractive layers which have different refractivity and are laminated alternately to form a laminated structure. Also disclosed is a monocrystalline silicon growth furnace, in which the thin-film heat insulation sheet is arranged on a heat shield. The thin-film heat insulation sheet has good reflectivity in wavelength ranges of heat radiation. When disposed on a heat shield to be applied to the monocrystalline silicon growth furnace, the thin-film heat insulation sheet not only can improve ability of the heat shield to reflect heat energy, reduce heat dissipation of molten silicon melt, and improve heat energy utilization, but also is conducive to heat insulation performance of the heat field, thereby improving the quality of the heat field to improve the quality and yield of monocrystalline silicon.

### CROSS REFERENCE TO RELATED APPLICATIONS

The present application claims the benefit of Chinese Patent Application No. 202010625055.7 filed on Jul. 1, 2020, the contents of which are incorporated herein by reference in their entirety.

### TECHNICAL FIELD

The present invention relates to the field of manufacturing of semiconductors, and in particular to a thin-film heat insulation sheet for a monocrystalline silicon growth furnace and a monocrystalline silicon growth furnace.

### BACKGROUND

Monocrystalline silicon plays an irreplaceable role as a material basis for sustainable development of industries of modern communication technology, integrated circuits, solar cells, and so on. At present, main methods for growing monocrystalline silicon from melt include the Czochralski method and the zone melting method. The Czochralski method for growing monocrystalline silicon has advantages of simple equipment and processes, easy to achieve automatic control, high production efficiency, easy preparation of a large-diameter monocrystalline silicon, as well as fast crystal growth, high crystal purity and high integrity, so that the Czochralski method has been rapidly developed.

To produce monocrystalline silicon in a monocrystalline silicon growth furnace using the Czochralski method, common silicon materials need to be melted and then recrystallized. According to the crystallization law of monocrystalline silicon, a raw material is heated and melted in a crucible, with a temperature controlled to be slightly higher than a crystallization temperature of silicon single crystal, to ensure that the molten raw material can be crystallized on the surface of the solution. The crystallized single crystal is pulled out of the liquid level through a pulling system of the Czochralski furnace, cooled and shaped under the protection of an inert gas, and finally crystallized into a crystal with a cylindrical body and a cone tail.

Monocrystalline silicon is grown in the heat field of the single crystal furnace, and thus the quality of the heat field significantly influences the growth and quality of the monocrystalline silicon. A good heat field can not only allow a single crystal to grow successfully, but also produce a high-quality single crystal. When heat field conditions are not sufficient, a single crystal may not be grown, and even though a single crystal is grown, the single crystal may be transformed to a polycrystal or has a structure with a large number of defects due to crystal transformation. Therefore, it is a very critical technology in a Czochralski monocrystalline silicon growth process to find better conditions and best configuration of the heat field. In the design of a heat field, the most critical is the design of a heat shield. Firstly, the design of the heat shield directly influences the vertical temperature gradient of the solid-liquid interface, and determines the crystal quality by influencing a V/G ratio with changed temperatures. Secondly, the design of the heat shield will influence the horizontal temperature gradient of the solid-liquid interface, and control the quality uniformity of the entire silicon wafer. Finally, a properly designed heat shield will influence the heat history of the crystal, and control nucleation and growth of defects inside the crystal. Therefore, the design of the heat shield is very critical in the process of preparing high-grade silicon wafers.

At present, an outer layer of a commonly used heat shield is a SiC coating layer or pyrolytic graphite, and an inner layer the commonly used heat shield heat-insulating graphite felt. The heat shield which is cylindric is positioned in an upper portion of the heat field. A crystal bar is pulled out of the cylindric heat shield. The graphite of the heat shield which is close to the crystal bar has a lower heat reflectivity and absorbs heat emitted from the crystal bar. The graphite on the outside surface of the heat shield usually has a higher heat reflectivity, which is beneficial to reflect back the heat emitted from the melt, thereby improving the heat insulation performance for the heat field and reducing power consumption of the whole process. However, the existing heat shields still have the defect of non-uniform temperature gradient.

In view of the above-mentioned defects in the prior art, the present invention is intended to provide a thin-film heat insulation sheet, which can be applied to a heat shield to improve the heat reflectivity of the heat shield, thereby increasing quality and yield of the crystal grown in the furnace.

### SUMMARY

In view of the abovementioned problems in the prior art, an objective of the present invention is to provide a thin-film heat insulation sheet for a monocrystalline silicon growth furnace, which comprises one or more first refractive layers and one or more second refractive layers which have different refractivity from that of the one or more first refractive layers, the one or more first refractive layers and the one or more second refractive layers are laminated alternately to form a laminated structure, and the first refractive layer is attached to the second refractive layer disposed adjacent thereto.

In a preferred embodiment, all the first refractive layers are made of silicon, and each of the first refractive layers has a thickness in a range from 0.1 mm to 0.8 mm and roughness of less than 1.4 A.

Alternatively, each of the first refractive layers has a thickness in a range from 0.1 mm to 0.3 mm and roughness of less than 1 A.

In a preferred embodiment, all the first refractive layers are made of molybdenum, and each of the first refractive layers has a thickness in a range from 0.5 mm to 3 mm and roughness of less than 10 A.

Alternatively, the first refractive layer has a thickness in a range from 1 mm to 2 mm and roughness of less than 3 A.

In a preferred embodiment, at least one of the first refractive layers in the laminated structure is made of silicon, and at least one of the first refractive layers in the laminated structure is made of molybdenum; the at least one of the first refractive layers made of silicon has a thickness in a range from 0.1 mm to 0.8 mm, and the at least one of the first refractive layers made of molybdenum has a thickness in a range from 0.5 mm to 3 mm.

In a preferred embodiment, the second refractive layers are made of silicon dioxide, and each of the second refractive layers has a thickness in a range from 0.1 mm to 1.5 mm and roughness of less than 2 A.

In a preferred embodiment, each of the second refractive layers has a thickness in a range from 0.1 mm to 0.5 mm and roughness of less than 1 A.

In a preferred embodiment, the thin-film heat insulation sheet is further provided with an encapsulation layer which is suitable for encapsulating the laminated structure.

In another aspect, a monocrystalline silicon growth furnace is provided in the present invention, which comprises a furnace body, a crucible, a heater unit, a heat shield, and a thin-film heat insulation sheet as described in the above technical solutions; wherein, the thin-film heat insulation sheet is provided on the heat shield;

a cavity is provided in the furnace body;

the crucible is arranged in the cavity and is used to contain melt for growth of monocrystalline silicon;

the heater unit is arranged between the crucible and the furnace body and is used to provide a heat field required for the growth of the monocrystalline silicon; and

the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

By adopting the aforementioned technical solutions, the present invention has the following beneficial effects:

The thin-film heat insulation sheet for a monocrystalline silicon growth furnace provided in the present invention has good heat reflectivity in the wavelength range of heat radiation. When disposed on a heat shield to be applied to the monocrystalline silicon growth furnace, the thin-film heat insulation sheet not only can improve ability of the heat shield to reflect heat energy, reduce heat dissipation of molten silicon melt, and improve heat energy utilization, but also is conducive to heat insulation performance of the heat field, thereby improving the quality of the heat field to improve the quality and yield of monocrystalline silicon.

### BRIEF DESCRIPTION OF DRAWINGS

In order to more clearly illustrate the technical solutions of the present invention, the drawings that are used in the description of the embodiments or the prior art will be briefly introduced hereafter. Obviously, the drawings in the following description are only some embodiments of the present invention, and other drawings can be obtained based on these drawings by those of ordinary skill in the art without creative work.

FIGS. 1A to 1E are schematic structural diagrams of thin-film heat insulation sheets for a monocrystalline silicon growth furnace according to an embodiment of the present invention;

FIGS. 2A to 2E are graphs showing heat reflectivity of the respective thin-film heat insulation sheets of FIGS. 1A to 1E;

FIGS. 3A to 3B are schematic structural diagrams of thin-film heat insulation sheets for a monocrystalline silicon growth furnace according to another embodiment of the present invention;

FIG. 4A is a graph showing the heat reflectivity of thin-film heat insulation sheet of FIG. 3A;

FIG. 4B is a graph showing the heat reflectivity of thin-film heat insulation sheet of FIG. 3B;

FIG. 5A to 5B are schematic structural diagrams of thin-film heat insulation sheets for a monocrystalline silicon growth furnace according to a further embodiment of the present invention;

FIG. 6A is a graph showing the heat reflectivity of thin-film heat insulation sheet of FIG. 5A; and

FIG. 6B is a graph showing the heat reflectivity of thin-film heat insulation sheet of FIG. 5B.

In the drawings: 10—first refractive layer, 10(I)—first refractive layer made of silicon, 10(II)—first refractive layer made of molybdenum, and 20—second refractive layer.

### DETAILED DESCRIPTION

Hereafter, the technical solutions according to embodiments of the present invention will be described clearly and thoroughly with reference to drawings. Obviously, the described embodiments are only part of, not all of, the embodiments of the present invention. Based on the embodiments of the present invention, all other embodiments obtained by those of ordinary skill in the art without any creative work shall fall within the protection scope of the present invention.

It should be noted that the terms “first”, “second”, or the like as used in the specification and claims of the present invention and in the above-mentioned drawings are used to distinguish similar objects, and are not intended to define a particular order or a sequential order. It should be understood that data used with reference to the terms may be interchanged, where appropriate, so that the embodiments of the present invention described herein can be implemented in an order other than those illustrated or described herein. In addition, the terms “comprising”, “including”, “having”, and any variations thereof, are intended to encompass non-exclusive inclusions.

### Embodiment 1

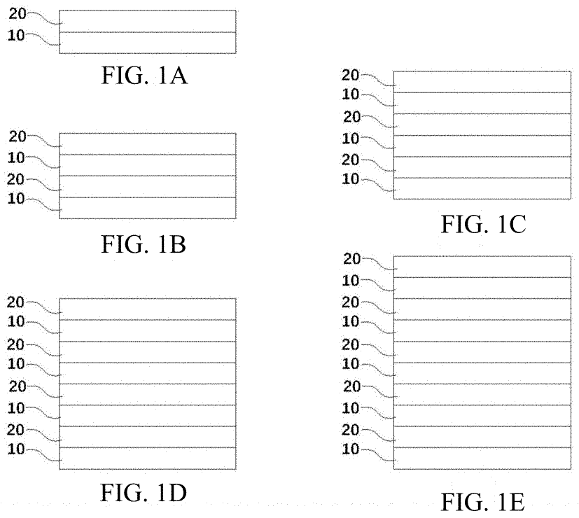

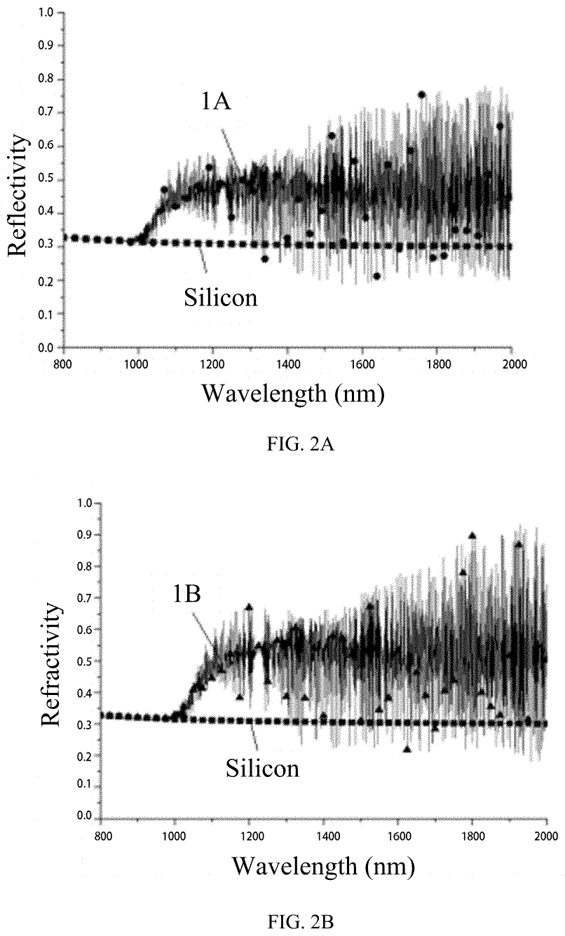

Refer to FIGS. 1A to 1E and FIGS. 2A to 2E. A thin-film heat insulation sheet for a monocrystalline silicon growth furnace according to the embodiment of the present invention comprises one or more first refractive layers 10 and one or more second refractive layers 20. The first refractive layer 10 and the second refractive layer 20 exist in pairs. The one or more first refractive layers 10 and the one or more second refractive layers 20 are laminated alternately to form a laminated structure. The first refractive layer 10 has different refractivity from that of the second refractive layer 20. The first refractive layer 10 is attached to the second refractive layer 20 disposed adjacent thereto, and the second refractive layer 20 is attached to the first refractive layer 10 disposed adjacent thereto. In other words, in the embodiment, the number of the first refractive layers 10 is equal to that of the second refractive layers 20, so that one side of the laminated structure is ended with the first refractive layer 10, and the other side of the laminated structure is ended with the second refractive layer 20. Refer to FIGS. 1A to 1E which respectively show thin-film heat insulation sheets in which the numbers of the first refractive layers (or the second refractive layers) are different and the numbers of the first refractive layers 10 are respectively 1, 2, 3, 4, and 5.

In the embodiment of the present invention, all the first refractive layers 10 in the laminated structures are made of silicon. Each of the first refractive layers 10 has a thickness in a range from 0.1 mm to 0.8 mm and roughness of less than 1.4 A. It should be noted that in the embodiment, the roughness refers to a root-mean-square roughness.

In the laminated structures, all the second refractive layers 20 are made of silicon dioxide. Each of the second refractive layers 20 has a thickness in a range from 0.5 mm to 3 mm and roughness of less than 2 A. Both the first refractive layer 10 and the second refractive layer 20 have low surface roughness, which is beneficial for good interface contact between the first refractive layer 10 and the second refractive layer 20, thereby improving heat reflectivity of the entire laminated structures.

The thin-film heat insulation sheet is further provided with an encapsulation layer (not shown) for encapsulating the laminated structure. The encapsulated thin-film heat insulation sheet is used to be disposed in a monocrystalline silicon growth furnace.

It should be noted that in the embodiment of the present invention, preparation processes for the first refractive layer 10 and the second refractive layer 20 are not limited. However, it should be understand that the final laminated structures have identical heat reflection effect, regardless of processes used to obtain the first refractive layer and the second refractive layer that meet the above requirements for thickness and roughness.

It should be noted that in these thin-film heat insulation sheets shown in FIGS. 1B to 1E, the laminated structures comprise two or more first refractive layers 10 and two or more second refractive layers 20. The first refractive layers 10 may each have the same thickness or different thicknesses, as long as each of the first refractive layers 10 has a thickness in a range from 0.1 mm to 0.3 mm. Likewise, the second refractive layers 20 may each have the same thickness or different thicknesses, as long as each of the second refractive layers 20 has a thickness in a range from 0.1 mm to 1.5 mm.

In particular, in the thin-film heat insulation sheets provided in the embodiment as shown in FIGS. 1A to 1E, each of the first refractive layers 10 is a silicon layer with a thickness of 0.1 mm, and each of the first refractive layers 10 has roughness of less than 1.4 A; and each of the second refractive layers 20 is a silicon dioxide layer with a thickness of 0.1 mm, and each of the second refractive layers 20 has roughness of less than 2 A.

Refer to FIGS. 2A to 2E which are graphs showing heat reflectivity of the thin-film heat insulation sheets with different numbers of the first refractive layer 10 and different numbers of the second refractive layer 20 provided in the embodiment, in which the horizontal coordinate represents wavelength (here, a wavelength in a range from 800 nm to 2000 nm is selected so as to correspond to the heat environment of the monocrystalline silicon growth furnace), and the vertical coordinate represents heat reflectivity. As can be seen from the graphs in FIGS. 2A to 2E, as compared to the heat insulation silicon sheet used in prior art, the thin-film heat insulation sheets having a laminated structure according to the embodiment have higher heat reflectivity in the heat field environment of the monocrystalline silicon growth furnace.

In addition, as the number of the first refractive layer—second refractive layer pairs increases, the number of interfaces formed by alternate arrangement of the first refractive layers 10 and the second refractive layers 20 also increases. When the number of the first refractive layer-second refractive layer pairs increases from one to three, the heat reflectivity of the thin-film heat insulation sheet is improved. However, when the number of the first refractive layer-second refractive layer pairs is four or more, the heat reflectivity graphs of the thin-film heat insulation sheets fluctuate more drastically, and a situation occurs where the heat reflectivity of the thin-film heat insulation sheet is lower than that of a thin-film silicon sheet at a wavelength in a range from 800 nm to 1100 nm, which is very detrimental for the overall heat reflectivity of the thin-film heat insulation sheet. Thus, it can also be seen that when the number of the first refractive layer-second refractive layer pairs is in a range from 2 to 3 and the interface number in the laminated structure is in a range from 3 to 5, the thin-film heat insulation sheets have better heat reflectivity. That is to say, improved heat reflectivity of the thin-film heat insulation sheet cannot be achieved by blindly increasing the number of the first refractive layer-second refractive layer pairs.

A monocrystalline silicon growth furnace is also provided according the embodiment of the present invention, which comprises a furnace body, a crucible, a heater unit, a heat shield, and a thin-film heat insulation sheet provided in the above-mentioned technical solutions, wherein the thin-film heat insulation sheet is disposed on the heat shield.

A cavity is provided in the furnace body.

The crucible is disposed in the cavity and located in the center of the cavity, wherein the crucible is recessed in the central portion and is used for containing melt for growth of monocrystalline silicon.

The crucible may be prepared from quartz (silicon dioxide), or may be prepared from graphite. Alternatively, the crucible may comprise an inner wall made of quartz material and an outer wall made of graphite material such that the inner wall of the crucible can directly contact silicon melt, and the outer wall of the crucible made of graphite can play a supporting role.

The heater unit is positioned around the crucible and between the crucible and the furnace body, thereby providing a heat field required for the growth of the monocrystalline silicon.

There is a space between the heater unit and the crucible. The space may be adjusted depending on parameters such as the size of the cavity, the size of the crucible, the heating temperature, and so on.

The heater unit is preferably a graphite heater unit. Further, the heater unit may comprise one or more heaters disposed around the crucible to make the heat field in which the crucible is located uniform.

The heat shield is disposed in an upper portion of the crucible, and is used to reflect heat energy emitted from the melt contained in the crucible, thereby playing a heat preservation role.

The thin-film heat insulation sheet is disposed on a side of the heat shield close to the crucible, and/or the thin-film heat insulation sheet is disposed on a side of the crucible close to the monocrystalline silicon grown.

Furthermore, the monocrystalline silicon growth furnace may also comprise a cooler for cooling a monocrystalline silicon ingot grown.

The crucible may also connected with an elevator mechanism and a rotation mechanism. The elevator mechanism is used to raise and lower the crucible. The rotation mechanism is used to rotate the crucible. The crucible can be raised/lowered and rotated in the heat field provided by the heater unit, which is beneficial to provide a good heat field environment. Thus, the silicon melt inside the crucible can also be positioned in a uniform heat environment.

When the thin-film heat insulation sheet according to the embodiment of the present invention is disposed on a heat shield to be applied to the monocrystalline silicon growth furnace, it not only can improve ability of the heat shield to reflect heat energy, reduce heat dissipation of molten silicon melt, and improve heat energy utilization, but also is conducive to heat insulation performance of the heat field, thereby improving the quality of the heat field to improve the quality and yield of monocrystalline silicon.

### Embodiment 2

In Embodiment 1, the first refractive layer 10 and the second refractive layer 20 exist in pairs. The thin-film heat insulation sheet provided according to Embodiment 2 differs from that of Embodiment 1 in that: in the thin-film heat insulation sheet provided in the embodiment, the number of the first refractive layers 10 is not equal to that of the second refractive layers 20.

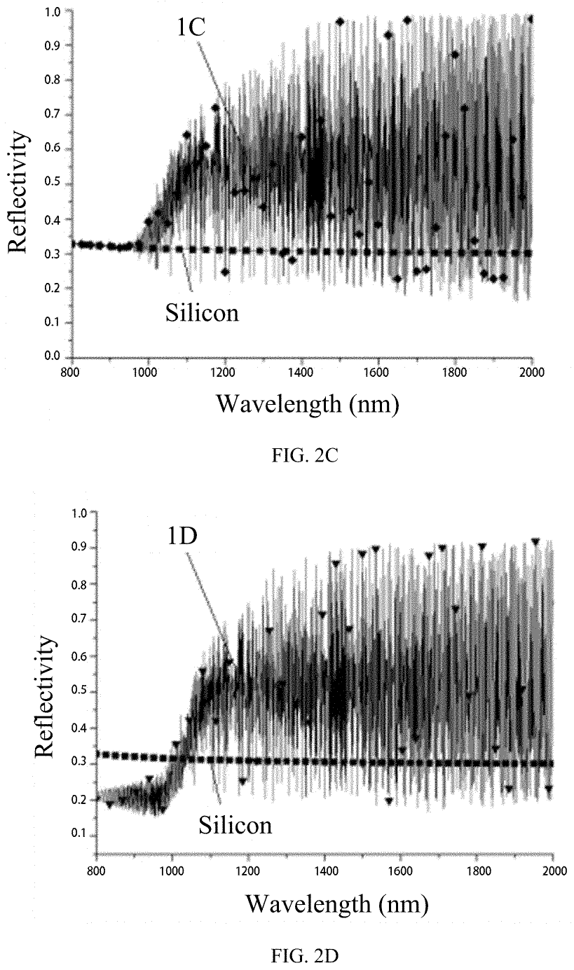

Refer to FIG. 3A. The thin-film heat insulation sheet provided in the embodiment comprises three first refractive layers 10 and two second refractive layers 20. The first refractive layers 10 have different refractivity from that of the second refractive layers 20. The first refractive layers 10 and the second refractive layers 20 are disposed alternately, such that each end of the laminated structure is the first refractive layer 10.

In the thin-film heat insulation sheet in FIG. 3A, each of the first refractive layers 10 is made of silicon. Here, a first refractive layer made of silicon is denoted as 10(I), and each of the first refractive layers 10(I) made of silicon has a thickness of 0.3 mm and roughness of less than 1 A. Each of the second refractive layers 20 is made of silicon dioxide, and has a thickness of 0.5 mm and roughness of less than 1 A.

Refer to FIG. 3B. The thin-film heat insulation sheet provided in the embodiment comprises three second refractive layers 20 and two first refractive layers 10. The first refractive layers 10 have different refractivity from that of the second refractive layers 20. The first refractive layers 10 and the second refractive layers 20 are disposed alternately, such that each end of the laminated structure is the second refractive layer 20.

In the thin-film heat insulation sheet in FIG. 3B, each of the first refractive layers 10 is made of molybdenum. Here, a first refractive layer made of molybdenum is denoted as 10(II), and each of the first refractive layers 10(I) made of molybdenum has a thickness of 0.5 mm and roughness of less than 10 A. Each of the second refractive layers 20 is made of silicon dioxide, and has a thickness of 01 mm and roughness of less than 2 A.

It should be noted that in the embodiment, the numbers of the first refractive layers 10 and the second refractive layers 20 are merely illustrative, and the numbers of the first refractive layers 10 and the second refractive layers 20 other than those provided in the embodiment may be used.

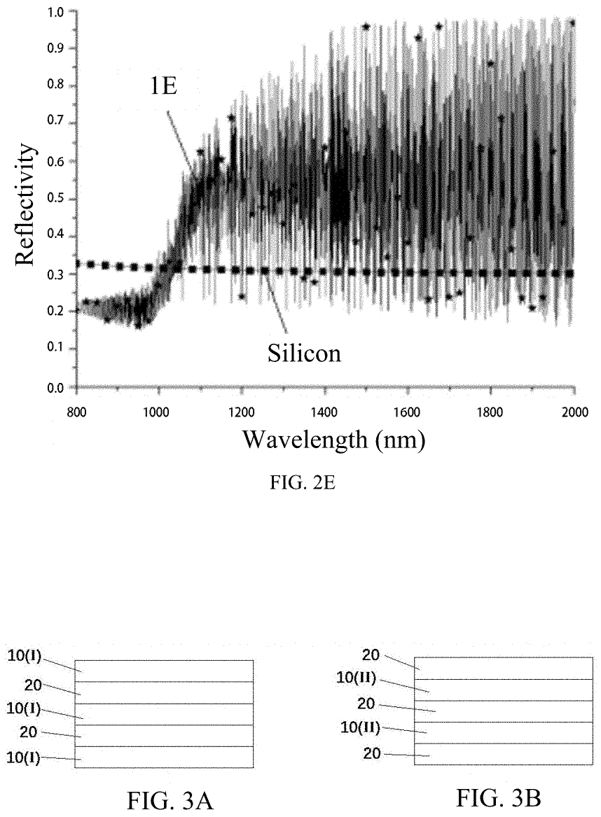

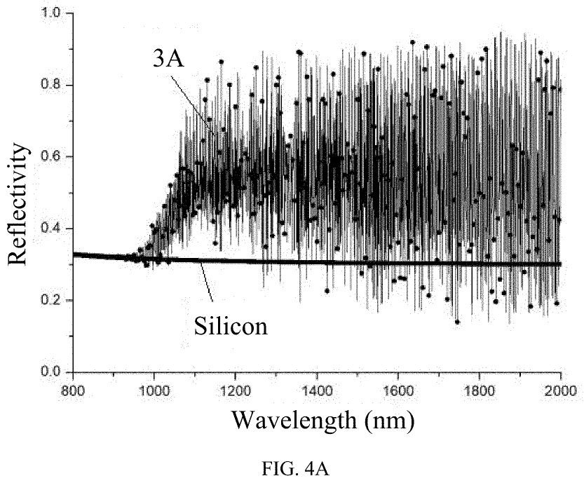

Refer to FIGS. 4A to 4B which are graphs showing heat reflectivity of the thin-film heat insulation sheets of FIGS. 3A to 3B, respectively. As can be seen from FIGS. 4A to 4B, since two thin-film heat insulation sheets both comprise four interfaces, the heat reflectivity thereof are comparable to that of the thin-film heat insulation sheet in FIG. 1C. Since the first refractive layers 10 of the thin-film heat insulation sheet in FIG. 3B are made of molybdenum, it can be deduced that improvement on the heat reflectivity of the thin-film heat insulation sheet in FIG. 3B is attributed to use of the first refractive layers made of molybdenum. Molybdenum has characteristics of high temperature resistance and high stability at high temperature.

### Embodiment 3

The thin-film heat insulation sheet according to the embodiment comprises first refractive layers 10 and second refractive layers 20 which have different refractivity from that of the first refractive layers 10, and the first refractive layers 10 and the second refractive layers 20 are disposed alternately. The thin-film heat insulation sheet of the embodiment differs from those of Embodiment 1 and Embodiment 2 in that:

There are at least two first refractive layers 10, wherein at least one of the first refractive layers 10 in the laminated structure is made of silicon, and at least one of the second refractive layers 20 in the laminated structure is made of molybdenum.

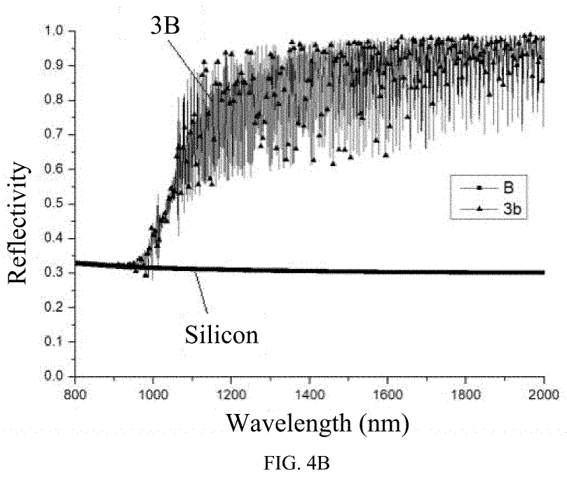

As an example, as shown in FIG. 5A, the thin-film heat insulation sheet for a monocrystalline silicon growth furnace provided in the embodiment in sequence comprises a first first refractive layer 10(I) made of silicon with a thickness of 0.8 mm, a first second refractive layer 20 made of silicon dioxide with a thickness of 0.3 mm and roughness of less than 1 A, a second first refractive layer 10(II) made of molybdenum with a thickness of 3 mm and roughness of less than 5 A, a second refractive layer 20 made of silicon dioxide with a thickness of 0.3 mm and roughness of less than 1 A, and a third first refractive layer 10(II) made of molybdenum with a thickness of 2 mm and roughness of less than 3 A.

As another example, as shown in FIG. 5B, another thin-film heat insulation sheet provided in the embodiment in sequence comprises a first refractive layer 10(II) made of molybdenum with a thickness of 2 mm and roughness of less than 3 A, a first second refractive layer 20 made of silicon dioxide with a thickness of 0.3 mm and roughness of less than 1 A, a second first refractive layer 10(I) made of silicon with a thickness of 0.5 mm and roughness of less than 1 A; and a second refractive layer 20 made of silicon dioxide with a thickness of 0.3 mm and roughness of less than 1 A.

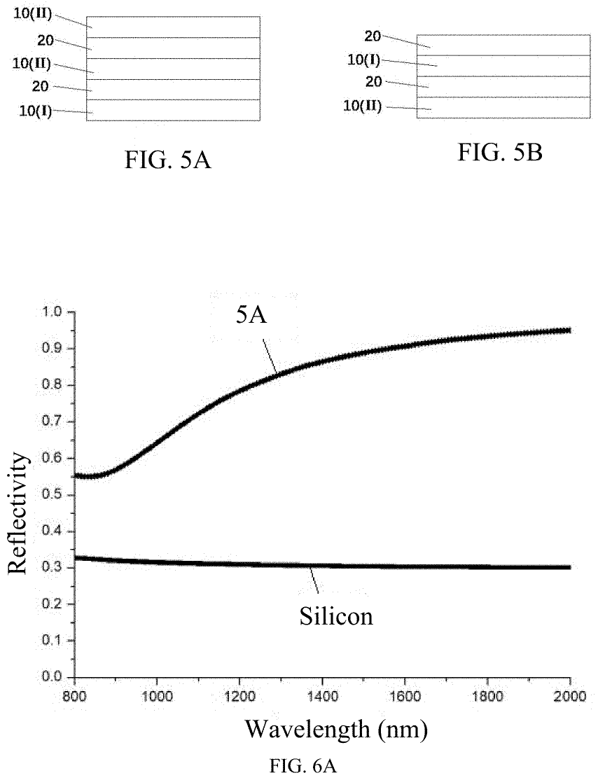

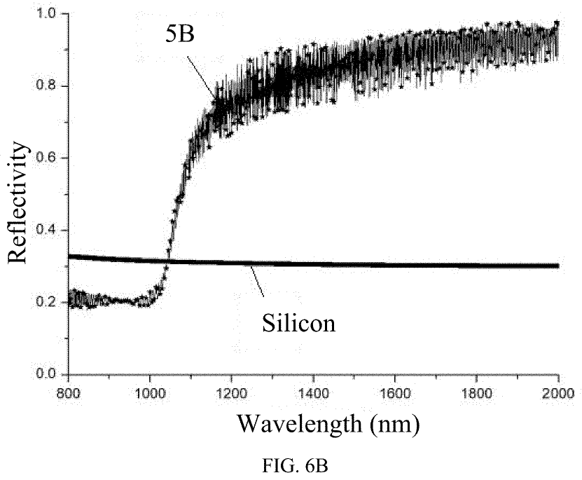

Refer to FIGS. 6A to 6B which are graphs showing heat reflectivity of the thin-film heat insulation sheets of FIGS. 5A to 5B, respectively. As shown in FIGS. 6A to 6B, the thin-film heat insulation sheet of FIG. 5A has excellent heat reflectivity, not only because the thin-film heat insulation sheet has four interfaces, i.e., a proper amount of interfaces, but also because three first refractive layers comprised therein comprise a first refractive layer 10(I) made of silicon and a first refractive layer 10(II) made of molybdenum, and the number of the first refractive layers 10(II) mad of molybdenum is larger than that of the first refractive layers 10(I) made of silicon. It should be noted that after a first refractive layer 10(I) made of silicon and a first refractive layer 10(II) made of molybdenum in the thin-film heat insulation sheet of FIG. 5A is exchanged in positions, the graph of heat reflectivity of the resultant thin-film heat insulation sheet is the same as that of the thin-film heat insulation sheet of FIG. 6A, which will not be reiterated here. By optimizing the thickness and roughness of each layer of the thin-film heat insulation sheet of FIG. 5A, the thin-film heat insulation sheet with optimum heat reflectivity can be obtained.

The thin-film heat insulation sheet of FIG. 5B has excellent heat reflectivity in a wavelength range from 1250 nm to 2000 nm (which is slightly higher than the reflectivity of the thin-film heat insulation sheet of FIG. 5A in this wavelength range), and has decreased heat reflectivity in a wavelength range from 800 nm to 1250 nm, which is detrimental for the overall heat reflectivity of the thin-film heat insulation sheet and may be attributed to the number of the interfaces and interface materials. However, the heat field environments are different for different monocrystalline silicon growth furnaces, and the wavelength ranges in which the heat reflectivity is high may also be different. Thus, the thin-film heat insulation sheet of FIG. 5B may also be used to in a growth furnace which has relatively high reflectivity in a wavelength range from 1250 nm to 2000 nm.

In summary, all the thin-film heat insulation sheets provided in the embodiments of the present invention have higher heat reflectivity than the heat insulation silicon sheet used in prior art. When the thin-film heat insulation sheets are disposed on heat shields to be applied in the monocrystalline silicon growth furnace, they not only can increase ability of the heat shields to reflect heat energy emitted from the silicon melt in the crucible, reduce heat dissipation of the molten silicon melt, and improve heat energy utilization, but also is conducive to heat insulation performance of the heat field, thereby improving the quality of the heat field to improve the quality and yield of monocrystalline silicon.

It should be noted that differences among the embodiments are described in the description of the present invention. In addition to the above embodiments, more thin-film heat insulation sheets other than those provided in the above embodiments can be obtained based on the features disclosed above by combining various layers in the thin-film heat insulation sheet.

The above-mentioned embodiments are preferred embodiments of the present invention, and are not intended to limit the present invention. It is apparent that to those skilled in the art that the present invention is not limited to the exemplary embodiments and can be implemented in other specific forms without departing from the spirit or essential features of the present invention. Therefore, from any point of view, the embodiments should be regarded as exemplary and non-limiting. All equivalent changes and modifications made in accordance with the present invention fall within the scope of the present invention defined by the attached claims. Any reference signs in the claims should not be regarded as limiting the claims involved.

1. A thin-film heat insulation sheet for a monocrystalline silicon growth furnace, wherein the thin-film heat insulation sheet for a monocrystalline silicon growth furnace comprises one or more first refractive layers (10) and one or more second refractive layers (20) which have different refractivity from that of the one or more first refractive layers (10), the one or more first refractive layers (10) and the one or more second refractive layers (20) are laminated alternately to form a laminated structure, and the first refractive layer (10) is attached to the second refractive layer (20) disposed adjacent thereto.

2. The thin-film heat insulation sheet for a monocrystalline silicon growth furnace of claim 1, wherein all the first refractive layers (10) are made of silicon, and each of the first refractive layers (10) has a thickness in a range from 0.1 mm to 0.8 mm and roughness of less than 1.4 A.

3. The thin-film heat insulation sheet for a monocrystalline silicon growth furnace of claim 2, wherein each of the first refractive layers (10) has a thickness in a range from 0.1 mm to 0.3 mm and roughness of less than 1 A.

4. The thin-film heat insulation sheet for a monocrystalline silicon growth furnace of claim 1, wherein all the first refractive layers (10) are made of molybdenum, and each of the first refractive layers (10) has a thickness in a range from 0.5 mm to 3 mm and roughness of less than 10 A.

5. The thin-film heat insulation sheet for a monocrystalline silicon growth furnace of claim 4, wherein each of the first refractive layers (10) has a thickness in a range from 1 mm to 2 mm and roughness of less than 3 A.

6. The thin-film heat insulation sheet for a monocrystalline silicon growth furnace of claim 1, wherein at least one of the first refractive layers (10) in the laminated structure is made of silicon, and at least one of the first refractive layers (10) in the laminated structure is made of molybdenum; the at least one of the first refractive layers (10) made of silicon has a thickness in a range from 0.1 mm to 0.8 mm, and the at least one of the first refractive layers (10) made of molybdenum has a thickness in a range from 0.5 mm to 3 mm.

7. The thin-film heat insulation sheet for a monocrystalline silicon growth furnace of claim 2, wherein the second refractive layers (20) are made of silicon dioxide, and each of the second refractive layers (20) has a thickness in a range from 0.1 mm to 1.5 mm and roughness of less than 2 A.

8. The thin-film heat insulation sheet for a monocrystalline silicon growth furnace of claim 4, wherein the second refractive layers (20) are made of silicon dioxide, and each of the second refractive layers (20) has a thickness in a range from 0.1 mm to 1.5 mm and roughness of less than 2 A.

9. The thin-film heat insulation sheet for a monocrystalline silicon growth furnace of claim 6, wherein the second refractive layers (20) are made of silicon dioxide, and each of the second refractive layers (20) has a thickness in a range from 0.1 mm to 1.5 mm and roughness of less than 2 A.

10. The thin-film heat insulation sheet for a monocrystalline silicon growth furnace of claim 7, wherein each of the second refractive layers (20) has a thickness in a range from 0.1 mm to 0.5 mm and roughness of less than 1 A.

11. The thin-film heat insulation sheet for a monocrystalline silicon growth furnace of claim 8, wherein each of the second refractive layers (20) has a thickness in a range from 0.1 mm to 0.5 mm and roughness of less than 1 A.

12. The thin-film heat insulation sheet for a monocrystalline silicon growth furnace of claim 9, wherein each of the second refractive layers (20) has a thickness in a range from 0.1 mm to 0.5 mm and roughness of less than 1 A.

13. The thin-film heat insulation sheet for a monocrystalline silicon growth furnace of claim 1, wherein the thin-film heat insulation sheet is further provided with an encapsulation layer which is suitable for encapsulating the laminated structure.

14. A monocrystalline silicon growth furnace, wherein the monocrystalline silicon growth furnace comprises a furnace body, a crucible, a heater unit, a heat shield, and a thin-film heat insulation sheet of claim 1; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

15. A monocrystalline silicon growth furnace, wherein the monocrystalline silicon growth furnace comprises a furnace body, a crucible, a heater unit, a heat shield, and a thin-film heat insulation sheet of claim 2; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

16. A monocrystalline silicon growth furnace, wherein the monocrystalline silicon growth furnace comprises a furnace body, a crucible, a heater unit, a heat shield, and a thin-film heat insulation sheet of claim 3; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

17. A monocrystalline silicon growth furnace, wherein the monocrystalline silicon growth furnace comprises a furnace body, a crucible, a heater unit, a heat shield, and a thin-film heat insulation sheet of claim 4; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

18. A monocrystalline silicon growth furnace, wherein the monocrystalline silicon growth furnace comprises a furnace body, a crucible, a heater unit, a heat shield, and a thin-film heat insulation sheet of claim 5; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

19. A monocrystalline silicon growth furnace, wherein the monocrystalline silicon growth furnace comprises a furnace body, a crucible, a heater unit, a heat shield, and a thin-film heat insulation sheet of claim 6; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.

20. A monocrystalline silicon growth furnace, wherein the monocrystalline silicon growth furnace comprises a furnace body, a crucible, a heater unit, a heat shield, and a thin-film heat insulation sheet of claim 13; the thin-film heat insulation sheet is provided on the heat shield;
a cavity is provided in the furnace body;
the crucible is arranged in the cavity and is used to contain melt for growth of monocrystalline silicon;
the heater unit is arranged between the crucible and the furnace body and is used to provide a heat field required for the growth of the monocrystalline silicon; and
the heat shield is arranged in an upper portion of the crucible and is used to reflect heat energy emitted from the crucible, and the thin-film heat insulation sheet is arranged on a side of the heat shield close to the crucible and/or the thin-film heat insulation sheet is arranged on a side of the crucible close to the monocrystalline silicon grown.
